(19) United States
(12) Patent Application Publication
(10) Pub. No.: US 2014/0132352 A1
(43) Pub. Date: May 15, 2014

(54) High Freqency Power Multiplier Solution

(71) Applicant: Ulrich Hansen, Stolberg (DE)

(72) Inventor: Ulrich Hansen, Stolberg (DE)

(73) Assignee: YXLON International GmbH, Stolberg-Vicht (DE)

(21) Appl. No.: 14/001,705

(22) PCT Filed: Jan. 17, 2012
(86) PCT No.: PCT/DE2012/000037

§ 371 Date: Oct. 3, 2013

(30) Foreign Application Priority Data
Feb. 28, 2011 (DE) 10 2011 012 622.8

(51) Int. Cl. G06G 7/14; H03F 3/21; H03F 3/193

(52) U.S. Cl. CPC G06G 7/14; H03F 3/193; H03F 3/211
USPC 330/295

(57) ABSTRACT

The invention relates to a high frequency power multiplier solution which enables multiple coupled high frequency power amplifier assemblies to be interconnected for adding individual powers thus avoiding the need of otherwise conventional and functionally complex functional groups of a power combiner.

The invention relates to a high-frequency power multiplier solution.

The considered subject matter involves narrow-band high-frequency (HF) power amplifiers and HF generators with transformer decoupling in a power range extending from a few watts to several kilowatts. The operating frequencies are in the megahertz range (typically 0.2 to 200 megahertz). HF power generators are taken to mean HF power amplifiers with the addition of their own, internal signal source. For the sake of simplicity only the term “power amplifier” will be used below as the invention relates to the power amplifier assemblies which form part of a complete power amplifier device or also a power generator device.

HF power amplifier assemblies in said power and frequency range are characterised in that their maximum power is essentially limited by the efficiency of the technologically and commercially available power semiconductor. However, many requirements need more power than a single amplifier assembly is able to produce. Typical applications are HF industrial generators, HF transmitters and HF power amplifiers for general high-power HF applications of over approximately 500 watts.

If the power of a single HF amplifier group is not sufficient, several of these HF amplifier assemblies must be interconnected, i.e. their power added to each other. This takes place by way of so-called “power combiners” which are familiar in various variants, depending on the frequency and power. Power combiners consist of an interconnection of HF leads and/or HF transformer(s), at least one power resistor and, if necessary, further capacitors and inductances for concentration and adjusting purposes. A power combiner has n inputs each with an impedance Z and a master output with typically (but not necessarily) the same impedance Z. On the basis of worldwide agreement the impedance Z is 50 ohms. However, for the functions it does not necessarily have to be set at ohms. The components to be used in a power combiner incur costs, require space and are very complex.

The aim of the present invention is to provide an improved HF power amplifier solution.

In accordance with a first aspect of the invention this is achieved by an HF power amplifier solution for HF power amplifier assemblies with transformer power decoupling, whereby the outputs of the power amplifier assemblies are serially connected. The serial connection of the outputs of the power amplifiers with transformer decoupling takes place in that in principle the secondary sides of the output transformers are connected in series. In this way an addition of the individual HF power of interconnected amplifier assemblies is possible. The invention allows power combiners to be dispensed with.

The HF power amplifier solution can be operated in a range of frequencies in the megahertz range and powers of several hundred watts, more particularly in a frequency range of over 10 megahertz, more particularly over 30 megahertz and a power range of over 100 watts, more particularly over 300 watts and again more particularly over 500 watts.

Advantageously the output impedance of each transformer decoupling for a number of n HF power amplifier assemblies is 1/n*Z of the desired output impedance Z. However other distributions are also entirely possible as the output impedance Z can be corrected by way of further measures.

The output impedance of the added amplifier assemblies is normally Z=50 ohms, but impedances differing therefrom are permissible for the functioning of the invention.

It is also advantageous if the HF power amplifier assemblies have secondary windings and a reactive component is arranged between the individual secondary windings of the HF power amplifier assemblies. This reactive component provides decoupling by the reactance value from one secondary to an adjacent secondary winding in the series coupling and thus from one amplifier assembly to another.

In a range from approximately 0.5 megahertz to 50 megahertz and 100 to 1000 watts and above in each case the decoupling is increasingly of advantage with increasing frequency and power, more particularly in the case of loads that are not ideal, such as unstable or reflecting loads. Overall, in addition to further advantages, smooth functioning with improved stability and robustness can be achieved in this way.

The reactive component preferably has a significant reactance value which should be of the order of the output impedance of a single HF power amplifier assembly. Preferably the reactive component has a reactance value of 20%-100% of the output impedance of a single HF power amplifier assembly. As greater reactance values can result in better decoupling the reactive component can also exhibit reactance values of more than 100% to several 100% of the output impedance.

The reactive component can be an inductor, a capacitor, a lead or a coupling of suchlike.

It is advantageous if the reactive component is one of the components within and a component part of a functional group that follows the interconnection of the HF power amplifier assemblies. By using this element no additional work or costs are necessary.

The reactive component is preferably located in the following functional assembly in series connects so its position in the series connection of transformer outputs and following filters can be changed.

Preferably the following functional group can be a deep pass filter or a band pass filter. A narrow-band HF power amplifier or one designed for a fixed frequency will generally include such a deep pass filter following the HF output. Additional work and costs are thus avoided.

It is advantageous if the reactive component can be divided into several parts so that the individual parts can be distributed at different points in the circuit.

A part of the reactive component which in accordance with the invention is arranged between the individual secondary windings of the HF power amplifier groups, can be arranged to earth between a transformer decoupling. This achieves an improved symmetry effect of the transformers. Advantageously the reactive component is divided into two partial inductances with 1/n*L and 1/m*L. The division is dimensioned so that the portion n results in sufficient decoupling and the portion m in sufficient symmetry support. The division can, for example, lead to L/2 and L/2. Other divisions are permissible.

Preferably the phasing of the HF output voltage of the HF power amplifier assemblies is the same. Through this identical phase control of the individual amplifier assemblies the HF voltage vectors are added in phase.

Finally it is advantageous if the power amplifier solution does not have an HF power resistor. This is always necessary in a power combiner. In the event of failure of one amplifier group this power resistor in the power combiner can become overloaded and thereby destroyed which usually leads to the entire device being switched off for safety. As such power resistors are dispensed with in the invention they cannot be destroyed in the event of failure of one of the amplifier assemblies which means an increase in the reliability of the device.

The invention will be described in more detail below with the aid of an example of embodiment with reference to the drawing.

Here

FIG. 1 shows a view of the individual amplifier assembly with transformer decoupling

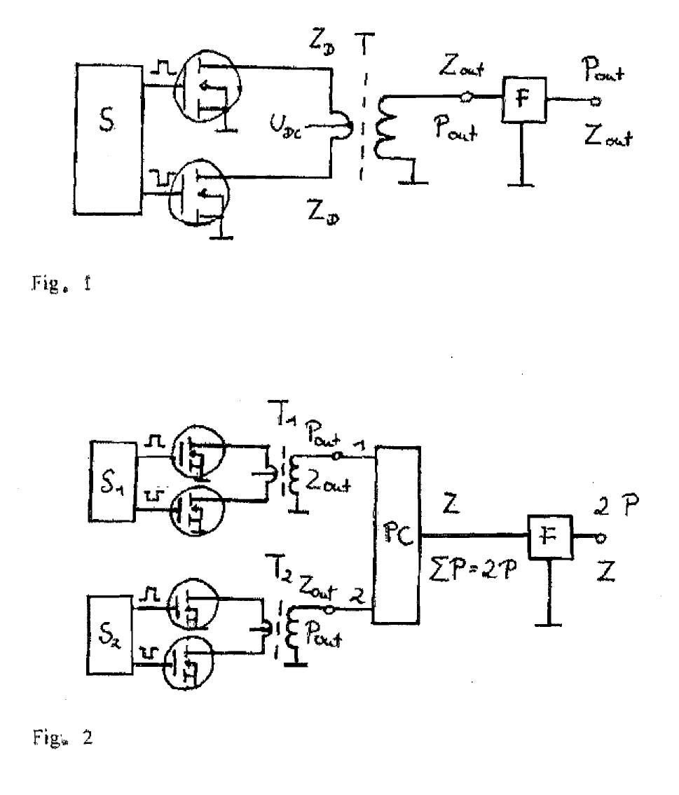

FIG. 2 show a diagram of the principle of interconnecting two power amplifiers with aid of a power combiner

FIG. 3 shows two typical power combiner circuits

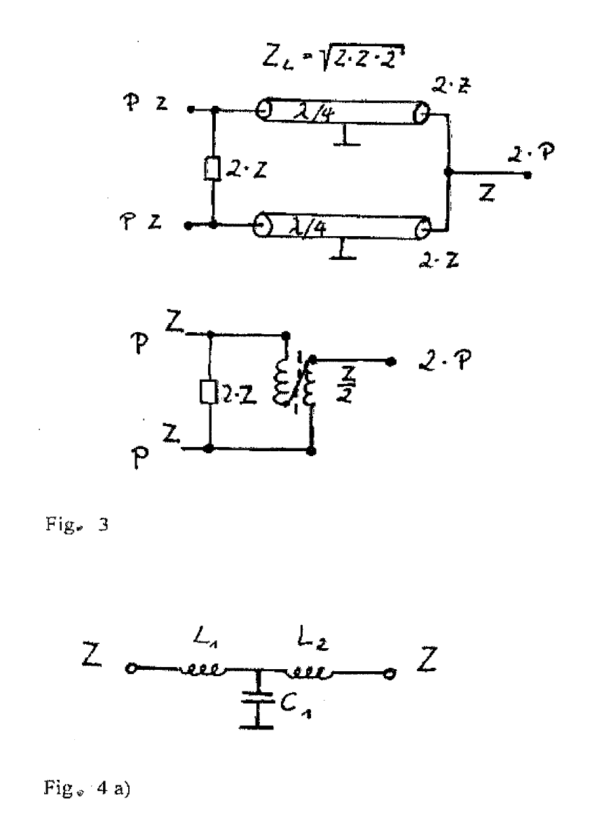

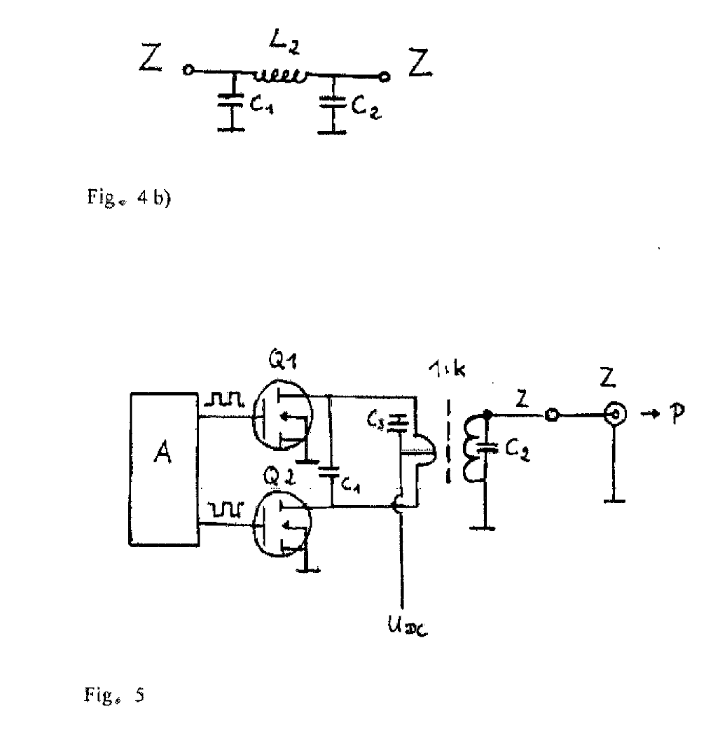

FIG. 4 shows two typical deep pass circuits

FIG. 5 shows a power amplifier assembly with transformer decoupling

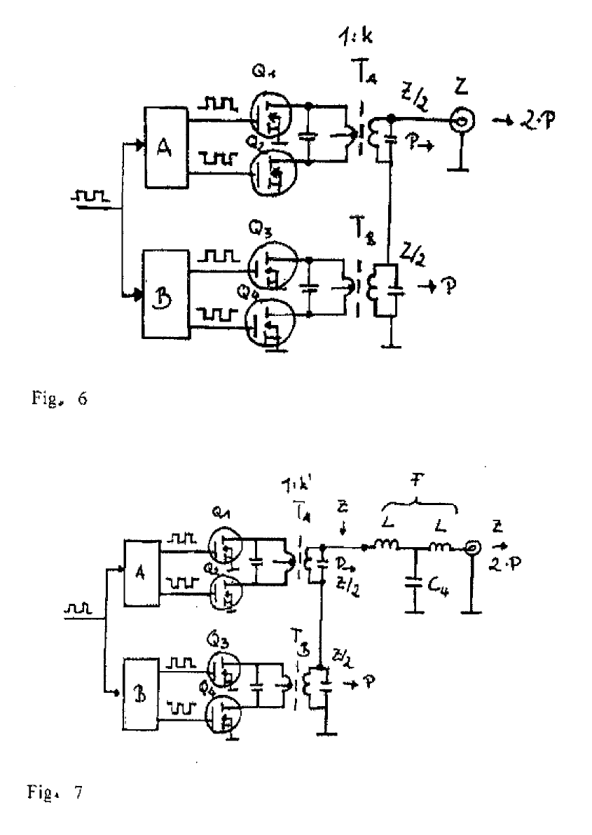

FIG. 6 shows a series interconnection of the secondary sides of several power amplifier components

FIG. 7 shows an HF power amplifier assembly in accordance with FIG. 6 with the addition of a deep pass filter

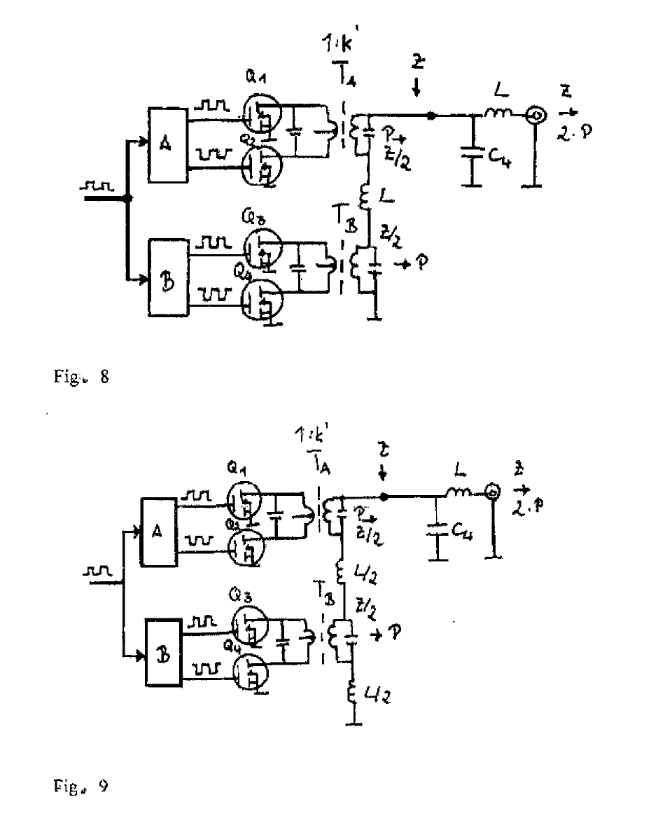

FIG. 8 shows an HF power amplifier assembly with an modified arrangement of the components of the deep pass filter and

FIG. 9 shows an HF power amplifier assembly with a further modified arrangement of the components of the deep pass filter.

The amplifier assembly in FIG. 1 essentially comprises an HF control and driver assembly S, two power HF transistors and the output transformer T as well as a downstream filter F.

In the principle diagram in FIG. 2 two power amplifier assemblies are shown which are interconnected by means of a power combiner PC. Each of the amplifier group consists of an HF control and driver assembly (S1 and S2), two power HF transistors and one transistor (T1 and T2). The filter F is downstream of the power combiner.

FIG. 3 shows typical variants of power combiners. In FIG. 3a) a Wilkinson Power Combiner and in FIG. 3b) a transformer power combiner are shown.

FIG. 4 shows two typical deep pass filter circuits to suppress undesirable harmonics. In FIG. 4a) a T deep pass filter is shown and FIG. 4b) a n filter. The simplified view in FIG. 5 shows a power amplifier assembly with transformer decoupling of the HF power. As an example a push-pull circuit is chosen as the HF power end stage. Although this is not absolutely necessary, the push-pull technology at the present power levels has decisive advantages compared with common mode technology. A hard switching HF control circuit A controls the gates of both power HF transistors Q1 and Q2. The increased HF voltage is applied to the drains so that a drain current occurs which is dependent on the impedance provided at the drain connection.

The impedance between the two drains of Q1 and Q2 is calculated from the winding ratio 1:k and the low impedance Z in accordance with the following equation:

Z drain-drain=Z load/k*k

Through the value of the load impedance Z, the suitable selection of the winding ratio k of the output transformer and the level of the DC operating voltage the drawn current is produced which results in a certain HF power. The maximum permitted manufacturing data of the power MOSFET must not be exceeded, which determines the maximum power obtainable from an individual power amplifier assembly. A first step of the invention is avoiding the power combiner through the series connection of the secondary sides of several power amplifier assemblies, hereinafter the two power amplifier groups in FIGS. 6, 11 and 12. The two power amplifier groups 11 and 12 are phased, i.e. the output signal of the amplifier A with Q1/Q2 is the same as that of amplifier B with Q3/Q4. The outputs of both amplifiers 11 and 12, that is the secondary sides of the HF transformers are connected in series which results in addition of the voltage. In order to retain the desired impedance at the master output of the combined amplifier assemblies, the output impedances of both groups 11 and 12 are half Z. After series connection the desired impedance is again obtained according to the equation 2*Z/2=Z. In the case of n amplifier assemblies the output impedance of each amplifier assembly is preferably set at Z/n. However, correction to the desired impedance Z can also be achieved through other measures.

As shown in 6 this approach still works in the case of series connection of transformers in the low-frequency range. However, its reliability fails in the HF frequency range. For this reason, in the state of the art the power combiner method in the HF range as a measure for adding several HF power amplifier assemblies has become the only widespread method in the HF range. In the series connection of secondary windings of the amplifier output transformers dangerous operating states for the operating the amplifiers and reduced efficiency occur as the interaction of one amplifier assembly with a next amplifier assembly does not allow the desired safe operation of HF power transistors through unavoidable coupling mechanisms between the secondary and primary side of the output transformers. The reasons why the series connection of HF transformer secondary windings has hitherto not be used are as follows. Firstly the available HF power transformers only have a finite functional quality. The coupling between their primary and secondary windings is not negligible in high frequency applications. In addition, the practical design of such transformers always results in small functional differences between transformer T_{A} and transformer T_{B}. The consequence of this is a non-identical HF output signal between amplifier assembly A and neighbouring amplifier assembly B.

Due to the non-identical output signal form and output signal amplitude equalisation a current flows, driven by the potential differences. Through the direct series connection of T_{A} and T_{B} shown in FIG. 6 these signal differences also couple from the secondary side of an HE transformer to its primary side. This produces a reverse effect of the primary effect of an HF transformer, which is directly connected to the drain of a power semiconductor (e.g. power MOSFET), via the internal MOSFET capacity Cgd (C drain-gate reverse capacity) to the controlling gate signal. This in turn lead to distortions of the HF gate control signal to no longer clearly definable sufficiently stable states of the power end stage. The instabilities become more severe with increase power levels and the series connection of HF amplifiers through the simple series connection of transformer outlets is therefore ruled out with further measures as a practically implementable solution.

HF power amplifier assemblies produce distortions and so-called harmonics. The generation and emission of harmonics are not permitted on legal grounds (international standards such as CE and FCC). In addition it is in the interest of every user to only be supplied with one operating frequency by the HF generator. For this reason filter measures are required and are usual downstream of the amplifier. In most cases for the sake of simplicity these are deep pass filters as shown in FIGS. 4a) and 4b). More rarely band pass filters are also used.

An HF power amplifier assembly in accordance with FIG. 6 has a deep pass filter in accordance with FIG. 4a) added in FIG. 7. For the sake of simplicity the deep pass filter is shown as a T-deep pass in the smallest configuration.

A narrow-band HF power amplifier or one designed for a fixed frequency will always include such a deep pass filter following the HF output.

As shown in FIG. 8 one of the reactive components of the filter can be used not only as a filter component, but by relocating it from the filter component to the output tract of the series-connected power amplifier groups as a reactance for the decoupling of the amplifier groups between the transformer output windings.

In the present example the inductance is released from the filter and moved between the secondary sides of transformer T_{A} and transformer T_{B}. According to the rule “any sequence of elements in the series connection” the reactance X of L has no impedance-distorting effect. The master output impedance of the overall amplifier Z is retained.

The repositioning of the inductance L from the filter between the two HF transformer outlets retains the function of the inductance L as a second deep pass filter. The effect of relevance to the invention of L being between the two transformers is a decoupling of the transformers T_{A} and T_{B}. The reactivity of the inductance L is designed so that its value X assumes the magnitude of the output impedance of the individual HF amplifier assembly XL. The reactance value should be at least a few umpteen percent of the output impedance of an amplifier group. Greater X values of the inductivity L support a better decoupling than a smaller X value of the impedance L.

Due to the connection of L between both outputs of the amplifier the X of the inductance L reduces or prevents the reciprocal influencing of both amplifier output and thereby the undesirable reciprocal back-coupling to the control circuits A and B. Defined and stable operation of the two HF amplifier group is guaranteed up to full power output.

A further step towards perfecting the concept is shown n FIG. 9. A further positive use of the inductance L can be achieved through a small modification in the circuit. Instead of arranging the inductance L between the two secondary windings of the transistors T_{A} and T_{B} the inductance is dimensioned into two inductances each with an individual inductance of L/2. The remaining L/2 is in the foot point of the amplifier outlet to earth. On the outlet side the transformer T_{B} is connected via L/2 instead of to earth. In this way an improved symmetry effect (balun effect with balun from balanced/unbalanced) of the transformer T_{B} is achieved, as the intrinsic balun effect of the transformer is provided with a further improvement in the balun behaviour through the use of the so-called “inductive layer” through the used ferrite cores.

The number of such series-connected amplifier groups is not limited to two. Limitation of the number is rationally and practically achieved through the operating frequency, the transformers and power transistors used as well as the magnitude of the inductance L, as, in order to achieve adequate decoupling, the value X of L divided by the number n of the amplifier groups must also of a significant magnitude in relation to the output impedance of the individual amplifier assembly.

1. An HF power amplifier solution for HF power amplifier assemblies with transformer decoupling, wherein outputs of the power amplifier assemblies are serially interconnected.

2. The HF power amplifier solution in accordance with claim 1, wherein it can be operated in a range of frequencies in the megahertz range and powers of several hundred watts.

3. The HF power amplifier solution in accordance with claim 1, wherein the output impedance of each transformer coupling for a number of HF power amplifier assemblies is 1/n*Z of the required output impedance Z.

4. The HF power amplifier solution in accordance with claim 1, wherein the HF power amplifier assemblies have secondary windings and a reactive component is arranged between the secondary windings of the HF power amplifier assemblies.

5. The HF power amplifier solution in accordance with claim 4, wherein the reactive component has a reactance value of the order of the output impedance of the individual HF power amplifier assembly.

6. The HF power amplifier solution in accordance with claim 4, wherein the reactive component has a reactance value of at least 20%-100% of the output impedance of an individual HF power amplifier group.

7. The HF power amplifier solution in accordance with claim 4, wherein the reactive component is an inductor, a capacitor, lead or an inter-coupling thereof.

8. The HF power amplifier solution in accordance with claim 4, wherein the reactive component is one of the components within, and an integral part of a functional group which follows the interconnection of the HF power amplifier assemblies.

9. The HF power amplifier solution in accordance with claim 8, wherein the reactive component is present in the following functional group in the series circuit.

10. The HF power amplifier solution in accordance with claim 8, wherein the reactive component can be divided into several parts.

11. The HF power amplifier solution in accordance with claim 8, wherein one part of the reactive component is arranged between a transformer decoupling to earth.

12. The HF power amplifier solution in accordance with claim 8, wherein the following functional group is a deep pass or band pass filter.

13. The HF power amplifier solution in accordance with claim 1, wherein the phasing of the HF output voltage of the HF power amplifier assemblies is identical.

14. The HF power amplifier solution in accordance with claim 1, wherein the HF power amplifier solution does not have an HF power resistance.
